(19) United States
(12) Patent Application Publication
(10) Pub. No.: US 2024/0234180 A1
(43) Pub. Date: Jul. 11, 2024

(54) WIPER FOR TRANSFERRING MICRO SEMICONDUCTOR CHIP AND APPARATUS FOR COLLECTING MICRO SEMICONDUCTOR CHIP

(71) Applicant: SAMSUNG ELECTRONICS CO., LTD., Suwon-si (KR)

(72) Inventors: Kyungwook HWANG, Suwon-si (KR); Youngtek Oh, Suwon-si (KR); Dongkyun Kim, Suwon-si (KR); Junsik Hwang, Suwon-si (KR); Minchul Yu, Suwon-si (KR)

(73) Assignee: SAMSUNG ELECTRONICS CO., LTD., Suwon-si (KR)

(21) Appl. No.: 18/409,400

(22) Filed: Jan. 10, 2024

(30) Foreign Application Priority Data
Jan. 10, 2023 (KR) 10-2023-0003512

(51) Int. Cl. H01L 21/67

(52) U.S. Cl. CPC H01L 21/67132

(57) ABSTRACT

Provided are a wiper for transferring a micro semiconductor chip and an apparatus for collecting a micro semiconductor chip. The wiper includes an absorber for absorbing a solution used to wet transfer a micro semiconductor chip, and a protective layer coated on the absorber.

### CROSS-REFERENCE TO RELATED APPLICATION

This application is based on and claims priority under 35 U.S.C. § 119 to Korean Patent Application No. 10-2023-0003512, filed on Jan. 10, 2023, in the Korean Intellectual Property Office, the disclosure of which is incorporated by reference herein in its entirety.

### BACKGROUND

### 1. Field

Embodiments of the disclosure relates to a wiper for transferring a micro semiconductor chip and an apparatus for collecting a micro semiconductor chip.

### 2. Description of the Related Art

The industrial demand for light emitting diodes (LEDs) has increased due to their low power consumption and environmental friendliness. Accordingly, LEDs are being widely used in various electronic devices such as lighting devices, liquid crystal display (LCD) backlights, and display devices. In order to manufacture display devices using micro semiconductor chips, a pick and place method has been widely used as a method of transferring micro semiconductor chips. However, the pick and place method has decreased productivity as the size of the micro semiconductor chips decreases and the size of displays increases.

### SUMMARY

Aspects of the disclosure provide a wiper for transferring a micro semiconductor chip and an apparatus for collecting a micro semiconductor chip. The wiper and the apparatus are capable of increasing a collection rate of a micro semiconductor chip, and as such, increase productivity of manufacturing a display device, even when the size of the micro semiconductor chips decreases and the size of displays increases.

Additional aspects will be set forth in part in the description which follows and, in part, will be apparent from the description, or may be learned by practice of the presented embodiments of the disclosure.

According to an aspect of the disclosure, there is provided a wiper including: an absorber configured to absorb a solution used to wet transfer a micro semiconductor chip; and a protective layer provided on the absorber, wherein the protective layer includes a material that does not chemically react to the solution.

The absorber may include one of fabric, tissue, polyester fiber, or paper.

The protective layer may include at least one of silk, photoresist, polydimethylsiloxane (PDMS), Teflon, or parylene.

The protective layer may be configured to prevent the micro semiconductor chip from penetrating into the absorber.

The protective layer may be configured to be removed by acetone (H2SO4/KOH/NaOH/toluene) or (ethanol/acetone) or removed by plasma etching.

The wiper may include a support configured to support the absorber, wherein the absorber is provided on the support.

The protective layer may be coated on the absorber.

The protective layer may be configured to reduce a number of micro semiconductor chips that penetrate into the absorber.

According to another aspect of the disclosure, there is provided a micro semiconductor chip collection apparatus including: a wiper configured to transfer a plurality of micro semiconductor chips, the wiper including: an absorber configured to absorb a solution used to wet transfer the plurality of micro semiconductor chips, and a protective layer provided on the absorber; a chip extraction module configured to remove one or more micro semiconductor chips stuck on the wiper from the wiper; and a protective layer removal module configured to supply a solution for removing the protective layer from the absorber.

The chip extraction module may include a liquid spray cleaner, an ultrasonic cleaner, or a vibration cleaner.

The absorber may include fabric, tissue, polyester fiber, or paper.

The protective layer may include a material that does not chemically react to the solution.

The protective layer may include at least one of silk, photoresist, polydimethylsiloxane (PDMS), Teflon, or parylene.

The protective layer is configured to prevent the micro semiconductor chip from penetrating into the absorber.

The protective layer may be configured to be removed by acetone (H2SO4/KOH/NaOH/toluene) or (ethanol/acetone) or removed by plasma etching.

The micro semiconductor chip collection may include a support configured to support the absorber, wherein the absorber is wrapped around the support.

The protective layer may be coated on the absorber.

The protective layer may be configured to reduce a number of micro semiconductor chips that penetrate into the absorber.

According to another aspect of the disclosure, there is provided a method of collecting a micro semiconductor chip including: providing a solution for forming a protective layer; forming a wiper by coating an absorber with the solution to form the protective layer on the absorber; transferring the micro semiconductor chip onto a transferring substrate using the wiper; and collecting the micro semiconductor chip by cleaning the transferring substrate and the wiper.

The method may include removing the protective layer from the absorber.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1 is a view illustrating a method of transferring a micro semiconductor chip according to an embodiment;

FIGS. 2A, 2B, and 2C illustrate a wiper for transferring a micro semiconductor chip according to an embodiment;

FIG. 3 illustrates an example of an absorber used in a wiper for transferring a micro semiconductor chip according to an embodiment;

FIG. 4 illustrates an operation of transferring a micro semiconductor chip, by using a wiper for transferring a micro semiconductor chip, according to an embodiment;

FIG. 5 schematically illustrates a state in which a micro semiconductor chip is stuck on a wiper for transferring a micro semiconductor chip according to an embodiment;

FIG. 6 schematically illustrates a state in which a protective layer is removed from a wiper for transferring a micro semiconductor chip according to an embodiment;

FIG. 7 is a flowchart illustrating a method of collecting a micro semiconductor chip according to an embodiment;

FIGS. 8 and 9 are views illustrating a method of coating a protective layer on an absorber for transferring a micro semiconductor chip according to an embodiment;

FIG. 10 schematically illustrates an apparatus for transferring a micro semiconductor chip according to an embodiment;

FIG. 11 illustrates an apparatus for collecting a micro semiconductor chip according to an embodiment;

FIG. 12 illustrates an apparatus for collecting a micro semiconductor chip according to an embodiment;

FIG. 13 illustrates an apparatus for collecting a micro semiconductor chip according to another embodiment; and

FIG. 14 illustrates an apparatus for collecting a micro semiconductor chip according to an embodiment.

### DETAILED DESCRIPTION

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, a wiper for transferring a micro semiconductor chip and an apparatus for collecting a micro semiconductor chip, according to various embodiments, will be described in detail with reference to the accompanying drawings. In the following drawings, the same reference numerals refer to the same components, and the size of each component in the drawings may be exaggerated for clarity and convenience of description. The terms first, second, etc. are only used to distinguish one element or component from another element or component and should not be interpreted in a limited way otherwise.

The singular forms are intended to include the plural forms as well, unless the context clearly indicates otherwise. In addition, when a portion “includes” or “comprises” a component, it means that it may further include other components, rather than excluding other components, unless specifically stated to the contrary. Also, the size or thickness of each component in the drawings may be exaggerated for clarity of description. In addition, when a certain material layer is referred to as being on a substrate or another layer, the material layer may be directly in contact with the substrate or the other layer, or another third layer may intervene therebetween. Also, a material described as forming each layer is illustrative, other materials may be used.

In addition, terms such as “ . . . or”, “module”, etc. used herein refer to units that process at least one function or operation, and the units may be implemented as hardware or software or as a combination of hardware and software.

Certain executions described in the embodiments are examples, and do not limit the technical scope in any way. For the simplicity of the description, the descriptions of existing electronic components, control systems, software, and other functional aspects may be omitted. In addition, connections or connecting units between components shown in the drawings are examples of functional connections and/or physical or circuit connections, and may be represented as alternative or additional various functional connections, physical connections, or circuit connections in real devices.

The use of the term “the” and similar indicative terms may correspond to both singular and plural forms.

Operations constituting a method may be performed in an appropriate order unless there is a clear statement that they should be performed in the order described. In addition, the use of all example terms (e.g., etc.) is simply intended to describe the technical spirit in detail, and the scope of the disclosure is not limited by these terms unless they are limited by claims.

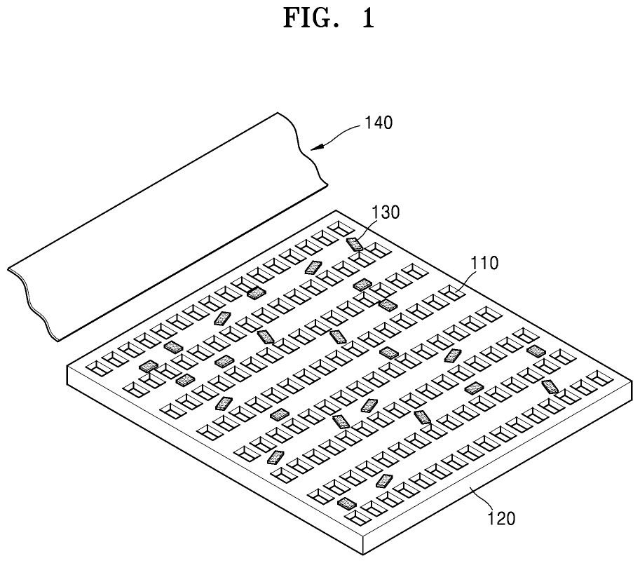

FIG. 1 is a view illustrating a method of transferring a micro semiconductor chip according to an embodiment.

According to an embodiment, a transferring substrate 120 including a plurality of grooves 110 may be provided. The transferring substrate 120 may be provided as a single layer or a plurality of layers. The groove 110 may be provided to arrange a micro semiconductor chip 130. The micro semiconductor chip 130 may include various types of semiconductor chips. The semiconductor chips may have a micro size. For example, the micro size may be 1,000 μm or less, or 200 μm or less. However, the disclosure is not limited thereto. The micro semiconductor chip 130 may include, for example, a light emitting diode (LED), complementary metal-oxide semiconductor (CMOS), a CMOS image sensor (CIS), a vertical-cavity surface-emitting laser (VCSEL), a photo diode (PD), a memory device, a two-dimensional (2D) material device, and the like. A 2D material may be graphene, carbon nanotube (CNT), or the like.

According to an embodiment, the method may include supplying liquid to the groove 110. The liquid may include any type of liquid that does not corrode or damage the semiconductor chip 130. The liquid may include, for example, water, ethanol, alcohol, polyol, ketone, halocarbon, acetone, flux, and organic solvent. In another embodiment, the liquid may include a combination (or a mixture) including one or more of water, ethanol, alcohol, polyol, ketone, halocarbon, acetone, flux, and organic solvent. The organic solvent may include, for example, isopropyl alcohol (IPA). An available liquid is not limited thereto, and various changes may be made according to another embodiment.

The method of supplying the liquid to the groove 110 may include, for example, various methods such as a spray method, a dispensing method, an inkjet dot method, and a method of allowing liquid flowing to the transferring substrate 120. An amount of liquid supplied may be variously adjusted to fit into the groove 110 or to overflow from the groove 110.

According to an embodiment, the method may include supplying a plurality of micro semiconductor chips 130 to the transferring substrate 120. The micro semiconductor chips 130 may be directly sprayed onto the transferring substrate 120 without any other liquid or may be supplied in a state of being included in a suspension. A method of supplying the micro semiconductor chips 130 included in the suspension may include various methods such as a spray method, a dispensing method of dropping liquid in droplets, an inkjet dot method of ejecting liquid like a printing method, and a method of allowing a suspension to flow onto the transferring substrate 120.

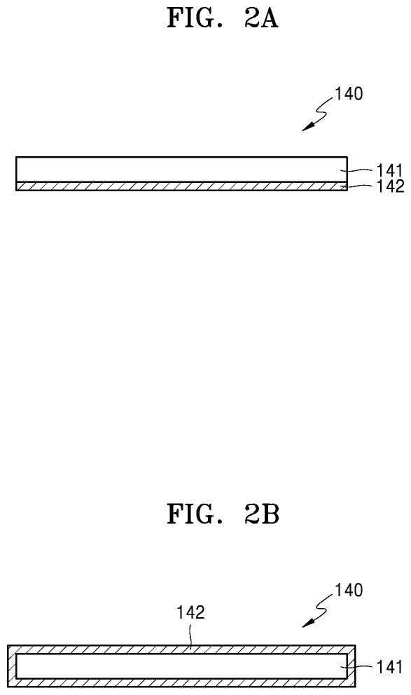

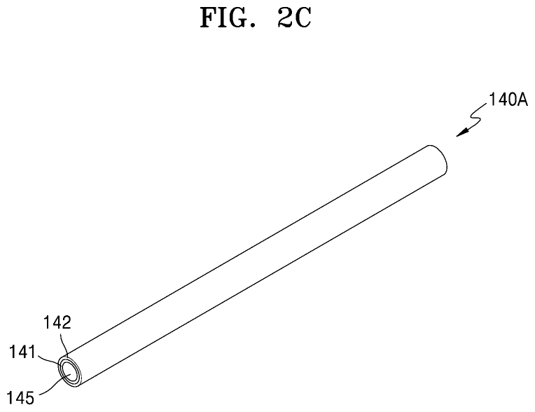

The transferring substrate 120 may be scanned by using a wiper 140. FIGS. 2A to 2C illustrate various examples of the wiper 140. Referring to FIG. 2A, a wiper 140 may include an absorber 141 capable of absorbing liquid and a protective layer 142 provided on the absorber 141 according to an embodiment. For example, the protective layer may be coated on the absorber 141. The protective layer 142 may be provided on one surface of the absorber 141. In an example case in which the protective layer 142 is provided only on one surface of the absorber 141, the micro semiconductor chip 130 may be scanned by using the surface on which the protective layer 142 is present, when the micro semiconductor chip 130 is transferred. According to another embodiment as illustrated in FIG. 2B, a protective layer 142 may be provided on the entire surface of an absorber 141. In this case, the protective layer 142 may be provided on all sides of the absorber 141, and thus, a wiper 140 may be used in any direction when the micro semiconductor chip 130 is transferred. In FIG. 2B, the protective layer 142 provided on the front side of the wiper 140 is omitted to illustration. Although FIGS. 2A and 2B illustrate embodiments in which the protective layer 142 is provided only on one side of the absorber 141 or the entire surface of an absorber 141, the disclosure is note limited thereto. As such, according to another embodiment, the protective layer 142 is provided on two or more surfaces of the absorber 141 or a partial region within a surface of the absorber 141.

As illustrated in FIG. 2C, a wiper 140A may include a support 145, an absorber 141, and a protective layer 142. The absorber 141 may be provided on the support or attached to the support. For example, the absorber 141 may be wrapped around a circumference of the support 145. The protective layer 142 may be provided on the absorber 141. The support 145 may fix the absorber 141 so that a scanning operation is stably performed. The support 145 may have various shapes. For example, the support 145 may have a circular cross section or a rectangular cross section, but the disclosure is not limited thereto. The absorber 141 may be used alone without other auxiliary devices, but is not limited thereto, and may be coupled to the support 145 to conveniently scan the transferring substrate 120. The support 145 may have various shapes and structures appropriate for scanning the transferring substrate 120. For example, the support 145 may have the shape of, for example, a rod, a blade, a plate, or the like. The absorber 141 may be provided on any one surface of the support 145, or may be wrapped around the circumference of the support 145.

The absorber 141 may be any material capable of absorbing liquid, and a shape or structure thereof is not limited. The absorber 141 may include, for example, fabric, tissue, polyester fiber, paper, or like.

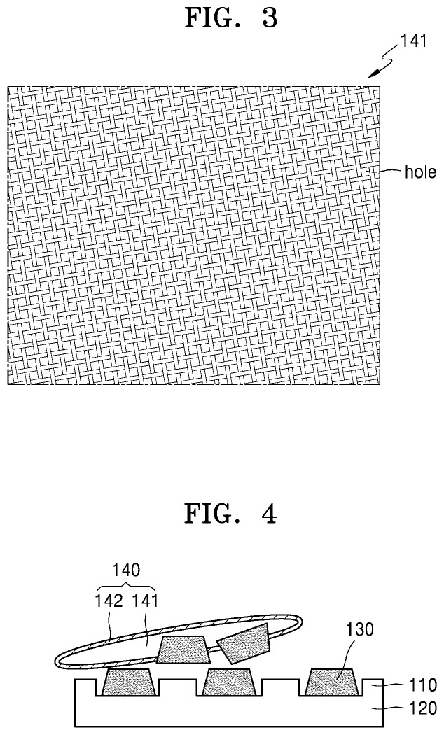

FIG. 3 illustrates an example of an absorber 141. According to an embodiment, fabric may be formed by interwinding horizontal thread (weft) and vertical thread (warp), and may have relatively greater strength than knitted fabric. The absorber 141 may have a mesh-shaped structure capable of absorbing liquid. The absorber 141 may have a plurality of mesh holes, and the mesh holes may have a smaller size than the micro semiconductor chips 130 to prevent the micro semiconductor chips 130 from being embedded or caught therein.

The wiper 140 may scan the transferring substrate 120 while pressing the transferring substrate 120 at appropriate pressure. Scanning may include an operation of the wiper 140 absorbing liquid while contacting the transferring substrate 120 and passing over the plurality of grooves 110. Scanning may be performed in various methods, such as a sliding method, a rotating method, a translating method, a reciprocating method, a rolling method, a spinning method, and/or a rubbing method of the wiper 140, and may include both a regular method and an irregular method. Scanning may also be performed by moving the transferring substrate 120 instead of moving the wiper 140, and scanning of the transferring substrate 120 may also be performed in a method such as sliding, rotating, translational reciprocating, rolling, spinning, or rubbing. Scanning may also be performed by cooperation between the wiper 140 and the transferring substrate 120.

An operation of supplying liquid to the grooves 110 of the transferring substrate 120 and an operation of supplying the micro semiconductor chips 130 to the transferring substrate 120 may be performed in reverse order. For example, the operation of supplying the micro semiconductor chips 130 to the transferring substrate 120 may be performed before an operation of supplying liquid to the grooves 110 of the transferring substrate 120. However, the disclosure is not limited thereto, and as such, the operation of supplying the liquid to the grooves 110 of the transferring substrate 120 and the operation of supplying the micro semiconductor chips 130 to the transferring substrate 120 may be simultaneously performed as one operation. For example, the liquid and the micro semiconductor chips 130 may be simultaneously supplied to the transferring substrate 120 by supplying a suspension including the micro semiconductor chips 130 to the transferring substrate 120.

According to an embodiment, the method may include after the wiper 140 scans the transferring substrate 120, removing dummy micro semiconductor chips, which remain on the transferring substrate 120. For example, the micro semiconductor chips which did not go into the grooves 110, during the scanning by the wiper 140, may be removed.

A process of transferring the micro semiconductor chips 130 is described in more detail below. Referring to FIG. 4, a wiper 140 may scan a transferring substrate 120 while contacting a surface of the transferring substrate 120. While scanning is in progress, a micro semiconductor chip 130 may be moved while adsorbed or attached onto a surface of the wiper 140. While scanning is in progress, the micro semiconductor chips 130 may be located between the wiper 140 and the transferring substrate 120, and the micro semiconductor chip 130 may go into a groove 110 while an absorber 141 of the wiper 140 absorbs liquid in the groove 110. A protective layer 142 may operate to protect the micro semiconductor chip 130 from being damaged. In addition, the protective layer 142 may reduce or prevent the micro semiconductor chip 130 from being embedded or stuck in the absorber 141 during a transfer process.

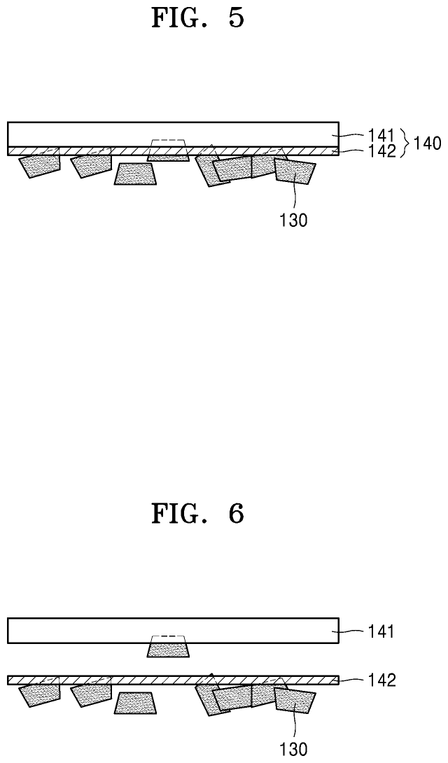

FIG. 5 illustrates a state in which a micro semiconductor chip 130 is stuck on a wiper 140 after transferring is completed. The micro semiconductor chip 130 may be mostly stuck on a protective layer 142 without penetrating into an absorber 141 due to the protective layer 142. In a case in which the micro semiconductor chip 130 penetrates into the absorber 141, the micro semiconductor chip 130 may not be easily extracted from the absorber 141 and collected. However, the protective layer 142 may prevent or reduce the micro semiconductor chip 130 from penetrating into the absorber 141, and thus, a collection rate of the micro semiconductor chip 130 may be increased. The micro semiconductor chip 130, which is stuck on the protective layer 142, may be easily separated and collected by a chip extraction module described below.

FIG. 6 illustrates a case in which a protective layer 142 is removed from an absorber 141. The protective layer 142 may be selectively removed from the absorber 141. The protective layer 142 may be removed by a wet method by using a solvent including acetone (H₂SO₄/KOH/NaOH/toluene) or (ethanol/acetone), or by a dry method through plasma etching. In a case in which the protective layer 142 is removed, the micro semiconductor chip 130 stuck on the protective layer 142 may be easily separated and collected.

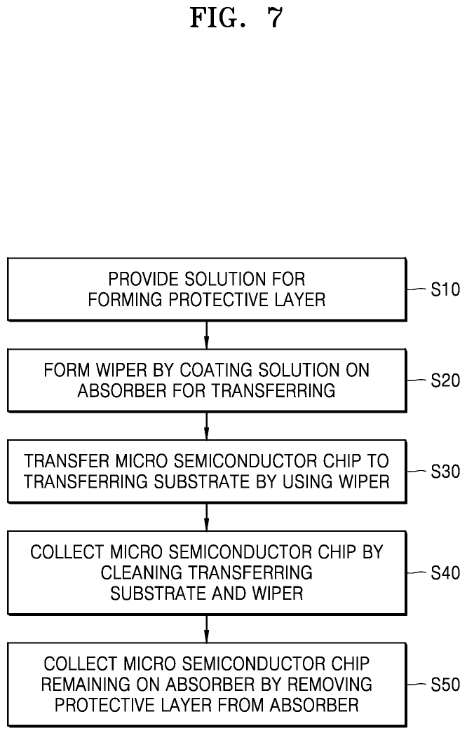

FIG. 7 is a flowchart illustrating a method of collecting a micro semiconductor chip according to an embodiment.

In operation S10, the method includes providing a solution for forming a protective layer. For example, a solution for coating a protective layer 142 onto an absorber may be provided. The solution for the protective layer 142 may include at least one of silk, photoresist, polydimethylsiloxane (PDMS), Teflon, or parylene. However, the disclosure is not limited thereto, and as such, the protection layer may be made of other materials.

In operation S20, the method may include coating the solution on the absorber 141. For example, the wiper 140 may be formed by coating the solution on the absorber 141 for transferring. In operation S30, the method may include transferring the micro semiconductor chip 130 to the transferring substrate 120 using the wiper 140. For example, the micro semiconductor chip 130 may be transferred to the transferring substrate 120 by using the wiper 140. In operation S40, the method may include collecting the micro semiconductor chip 130 by cleaning the transferring substrate 120 and the wiper 140. For example, the micro semiconductor chip 130 may be collected by cleaning the transferring substrate 120 and the wiper 140. The micro semiconductor chip 130 stuck on the wiper 140 may be mostly stuck on the protective layer 142 without deeply penetrating into the absorber 141 due to the protective layer 142, and thus may be easily separated and come out in a cleaning operation. Therefore, a collection rate of the micro semiconductor chip 130 may be increased. A polar solvent may be used as a cleaning solvent. The polar solvent may include water, ethanol, or acetone. The cleaning solvent may include, for example, acetone (H₂SO₄/KOH/NaOH/toluene) or (ethanol/acetone).

In operation S50, the method may include removing the protective layer 142 from the absorber 141. For example, the micro semiconductor chip 130 remaining on the absorber 141 may be collected by removing the protective layer 142 from the absorber 141. A polar solvent may be used as a solution for removing the protective layer 142. The solution for removing the protective layer 142 may include, for example, acetone (H₂SO₄/KOH/NaOH/toluene) or (ethanol/acetone), or may remove the protective layer 142 by a dry etching method using plasma etching. Operation S50 may be selectively performed.

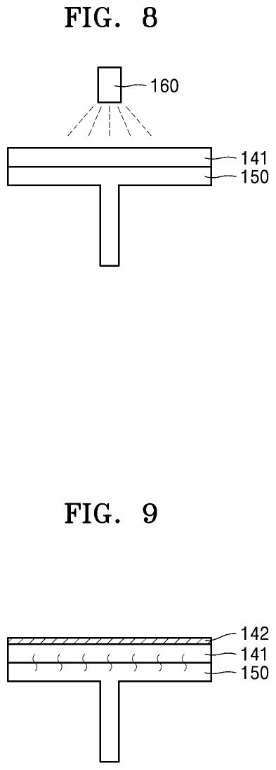

FIG. 8 illustrates an example of a method of coating a protective layer on an absorber 141.

The absorber 141 may be mounted on a support plate 150, and a solution for coating a protective layer may be sprayed onto the absorber 141 by using a sprayer 160. A spray method or a spin coating method may be used to coat the protective layer.

FIG. 9 illustrates that a protective layer 142 sprayed on an absorber 141 is baked and hardened.

The role of the absorber 141 capable of absorbing a transfer solution may be significant in a method of transferring a micro semiconductor chip. The absorber 141 may operate as a buffer when generating physical contact with the micro semiconductor chip 130 in a transferring operation, and may also generate contact forces in various directions that direct or lead the micro semiconductor chip 130 onto grooves 110. Due to the role of absorbing the transfer solution, the absorber 141 may effectively generate a force capable of dragging the micro semiconductor chip 130. However, hard chips may be embedded inside the absorber 141 due to the buffering action of the absorber 141 described above. Accordingly, a method of effectively collecting the micro semiconductor chips 130 stuck on the absorber 141 after a transfer process is needed. Chips remaining on the absorber 141 may be removed by a physical force, but chips deeply embedded inside the absorber 141 having a textile structure may not be easily collected. The wiper 140 according to an embodiment may easily increase a collection rate of remaining chips by coating the protective layer 142 on the absorber 141. The protective layer 142 may include a material that does not react to a solution used in a transfer process, and may include a material that does not generate foreign substances in the transfer process and may be easily removed in a chip collection process.

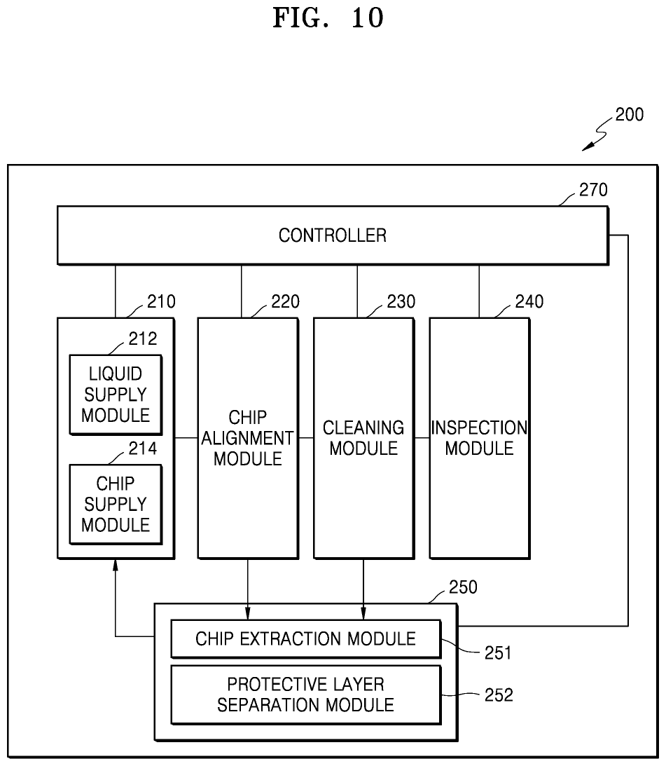

FIG. 10 schematically illustrates a micro semiconductor chip wet transferring apparatus.

Referring to FIG. 10, a micro semiconductor chip wet transferring apparatus 200 may include a wet chip supply module 210, a chip alignment module 220, and a chip collection apparatus 250. Referring to FIGS. 1 and 10, the wet chip supply module 210 may include a liquid supply module 212 that supplies liquid onto a transferring substrate and a chip supply module 214 that supplies a plurality of micro semiconductor chips 130. The liquid supply module 212 and the chip supply module 214 may be separately provided, but the disclosure is not limited thereto. As such, according to another embodiment, the wet chip supply module 210 may be configured as a single module to include a suspension including the micro semiconductor chips 130 and supply the suspension to the transferring substrate 120.

The chip alignment module 220 may transfer the micro semiconductor chips 130 to the transferring substrate 120 by using the wiper 140.

The chip collection apparatus 250 may include a chip extraction module 251 that extracts the micro semiconductor chip 130 remaining on the wiper 140, and a protective layer separation module 252 that separates the protective layer 142 from the absorber 141.

The micro semiconductor chip wet transferring apparatus 200 may further include a cleaning module 230, an inspection module 240, and a controller 270.

The cleaning module 230 may be configured to remove a dummy micro semiconductor chip remaining on a surface of the transferring substrate 120 after a plurality of micro semiconductor chips 130 are completely aligned in a plurality of grooves 110 by the chip alignment module 220. The cleaning module 230 may remove the dummy micro semiconductor chip in various methods. The cleaning module 230 may include, for example, an absorber or a wiper 140, and may remove the dummy micro semiconductor chip while moving in contact with the transferring substrate 120 via the new absorber.

The inspection module 240 may inspect a state of the transferring substrate 120. The inspection module 240 may be a camera capable of analyzing a high-resolution image. The inspection module 240 may inspect the state of the transferring substrate 120 through image analysis.

As an example, the inspection module 240 may inspect an alignment state of the micro semiconductor chip 130 on the transferring substrate 120. Based on the result of the inspection by the inspection module 240, the controller 270 may control at least one of the wet chip supply module 210 and the chip alignment module 220 to operate. Accordingly, alignment accuracy of a plurality of micro semiconductor chips 130 may be improved.

For example, as the result of the inspection by the inspection module 240, a location of the groove 110 in which the micro semiconductor chip 130 is missing may be identified from among the grooves 110 of the transferring substrate 120. In this case, based on the result of the inspection by the inspection module 240, the controller 270 may control at least one of the wet chip supply module 210 and the chip alignment module 220 to operate based on the location of the groove 110 in which the micro semiconductor chip 130 is missing.

As another example, the inspection module 240 may inspect a supply state of the micro semiconductor chip 130 and liquid, on the transferring substrate 120. For example, the inspection module 240 may inspect whether or not liquid is present on the transferring substrate 120 or whether or not the liquid is sufficient even when the liquid is present on the transferring substrate 120. Based on the result of the inspection by the inspection module 240, the controller 270 may control the liquid supply module 212 to operate.

For example, the inspection module 240 may inspect whether or not the micro semiconductor chips 130 are present on the transferring substrate 120 or whether or not the micro semiconductor chips 130 are sufficient even when the micro semiconductor chips 130 are present on the transferring substrate 120. Based on the result of the inspection by the inspection module 240, the controller 270 may control the chip supply module 214 to operate.

As described above, the controller 270 may improve alignment accuracy of a plurality of micro semiconductor chips 130 by controlling at least one of the wet chip supply module 210 and the chip alignment module 220 to operate, based on the result of the inspection result by the inspection module 240. The controller may be implemented by a hardware, a software or a combination of hardware and software. For example, the controller may be implemented by a memory storing one or more instructions and a processor configured to execute the one or more instructions to perform the operations of the controller 270 described above.

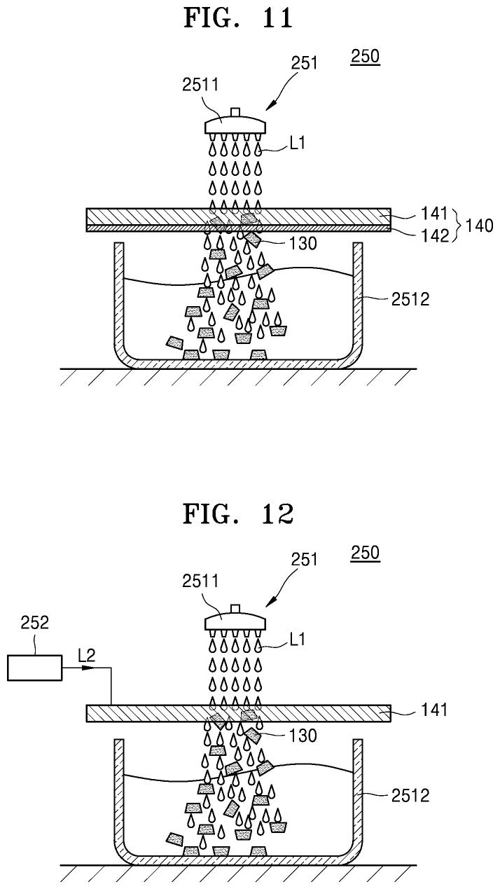

FIG. 11 illustrates an example of a micro semiconductor chip collection apparatus 250.

The micro semiconductor chip collection apparatus 250 may scan the transferring substrate 120 by using a wiper 140 and then extract and collect micro semiconductor chips 130 remaining on the wiper 140. FIG. 11 illustrates an example in which a chip extraction module 251 is implemented as a liquid spray cleaner 2511. The micro semiconductor chip collection apparatus 250 may include, for example, the liquid spray cleaner 2511 configured to extract the micro semiconductor chip 130 from the wiper 140 by spraying liquid L1 onto the wiper 140. In an example case, most of the micro semiconductor chip 130 may not be deeply embedded in an absorber 141 due to a protective layer 142 provided on the absorber. Instead, the micro semiconductor chip 130 may be mostly stuck on the protective layer 142, and thus may be easily collected by the liquid spray cleaner 2511. The liquid spray cleaner 2511 may be arranged at various locations at which the liquid spray cleaner 2511 may effectively extract the micro semiconductor chip 130 from the wiper 140. For example, the liquid spray cleaner 2511 may be located above the wiper 140, and spray the liquid L1 toward the wiper 140 to remove the micro semiconductor chip 130 remaining on the wiper 140 from the wiper 140. A water tank 2512 may be provided under the wiper 140, and the micro semiconductor chip 130 removed from the wiper 140 may be collected into the water tank 2512.

In addition, the liquid spray cleaner 2511 may be movably configured to evenly spray the liquid L1 onto the entire region of the wiper 140 or selectively spray the liquid L1 onto a needed region.

The liquid spray cleaner 2511 may include a pressure apparatus, a flow control valve, a solenoid valve, a pressure gauge, and one or more nozzles to spray high-pressure liquid drops. The spray region of the liquid drops may be configured to be greater than a region to which a micro semiconductor chip is stuck in a scanning process. The liquid spray cleaner 2511 may include a plurality of nozzles to simultaneously spray liquid onto a large region of the wiper 140, or may be configured to spray liquid while moving one nozzle. When the liquid spray cleaner 2511 includes one nozzle, the liquid spray cleaner 2511 may be configured to spray liquid while rotating the nozzle.

The liquid L1 may include any type of liquid that does not corrode or damage the micro semiconductor chip 130 and the absorber 141. For example, the liquid L1 may include at least one of water, ethanol, alcohol, polyol, ketone, halocarbon, acetone, flux, or organic solvent. The organic solvent may include, for example, isopropyl alcohol (IPA). The liquid L1 is not limited thereto, and various changes may be made according to another embodiment.

When the liquid L1 is capable of removing the protective layer 142, the micro semiconductor chip 130 may be further effectively collected while the protective layer 142 is removed when the liquid L1 is sprayed from the liquid spray cleaner 2511.

FIG. 12 illustrates an example in which a protective layer separation module 252 first removes the protective layer 142 from a wiper 140, and a liquid spray cleaner 2511 may spray liquid L1 onto an absorber 141 to collect a micro semiconductor chip 130. The protective layer separation module 252 may supply liquid L2 capable of removing the protective layer 142.

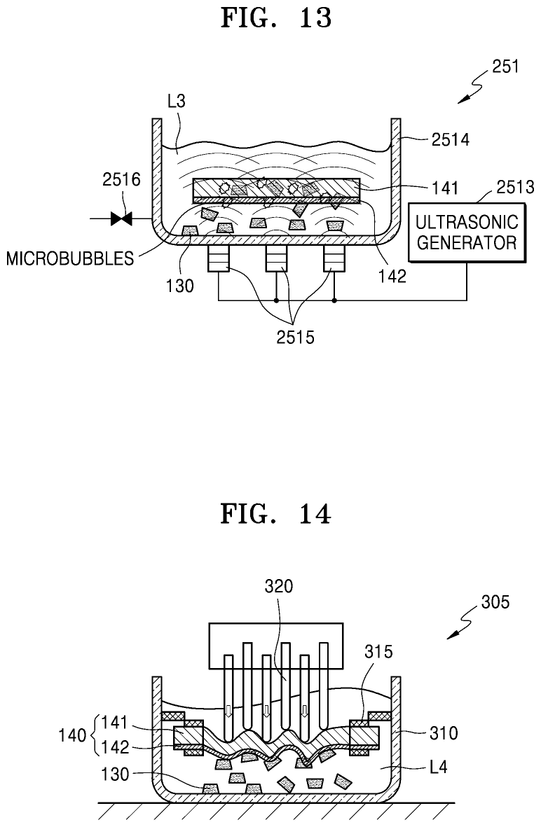

FIG. 13 illustrates an example in which a chip extraction module 251 implemented as an ultrasonic cleaner.

The chip extraction module 251 may be configured to extract a micro semiconductor chip 130 from an absorber 141 by emitting ultrasonic waves to the absorber 141. The chip extraction module 251 may include a water tank 2514 for containing liquid L3, an ultrasonic transducer 2515 attached underneath the water tank 2514 to generate ultrasonic waves, and an ultrasonic generator 2513 for applying an electrical signal having a certain frequency to the ultrasonic transducer 2515. An inner wall of the water tank 2514 may be surface-treated to prevent the micro semiconductor chip 130 from being stuck. For example, the inner wall of the water tank 2514 may include a material to which the micro semiconductor chip 130 is not stuck.

The ultrasonic transducer 2515 may be coupled to the water tank 2514 containing the liquid L3 to vibrate the water tank 2514, and extract the micro semiconductor chip 130 stuck on the absorber 141 or the protective layer 142 by generating micro-bubbles by vibration energy. The extracted micro semiconductor chip 130 may sink to a bottom of the water tank 2514, and a valve 2516 coupled to the water tank 2515 may be opened to collect the micro semiconductor chip 130.

The chip extraction module 251 may extract the micro semiconductor chip 130 from the absorber 141 and the protective layer 142 by using cavitation of ultrasonic waves. The cavitation refers to a phenomenon in which microbubbles (cavities) are generated in the liquid L3 due to a change in pressure due to a change in velocity of the liquid L3 when ultrasonic waves propagate into a medium, e.g., the liquid L3. The micro-semiconductor chip 130 may be extracted by using the cavitation effect and particle acceleration effect of the ultrasonic waves. By using the principle described above, the micro semiconductor chip 130 stuck between surfaces and internal tissues of the absorber 141 and the protective layer 142 may be easily removed. The microbubbles generated during the propagation of the ultrasonic waves may permeate not only into the surfaces of the absorber 141 and the protective layer 142 but also into the absorber 141 and burst under high pressure to generate energy. Accordingly, the micro semiconductor chips 130 remaining on the surface and inside of the absorber 141 and the protective layer 142 may come out.

A cavitation strength may be proportional to surface tension of the liquid L3 and inversely proportional to a frequency, an amount of dissolved gas, and vapor pressure of a solution. Therefore, when a temperature of the liquid L3 increases, the cavitation strength may weaken, and thus, ultrasonic cleaning may be performed at room temperature. When the amount of dissolved gas is large, the cavitation strength may be lowered, and thus, a solution with a small amount of dissolved gas may be used.

In an case in which an ultrasonic frequency increases, the cavitation strength may weaken, and thus, a physical force applied to the absorber 141 and the protective layer 142 may decrease. However, a cavitation density may increase, and thus, a penetration force may be improved. Therefore, selection of an appropriate frequency may be significant. For example, the ultrasonic cleaner generator 2513 may include a frequency in a range from 25 kHz to 60 kHz.

In an example in which the surface tension of the liquid L3 decreases, the cavitation strength may weaken and a physical force applied to the absorber 141 and the protective layer 142 may decrease, but the cavitation density may increase, and thus, the penetration force may be improved. Acetone or ethanol has a lower surface tension than water, and thus, the cavitation strength may be low, but the penetration force may be improved. The surface tension may be adjusted by mixing water with acetone or ethanol. The protective layer 142 may also be selectively removed from the chip extraction module 251 illustrated in FIG. 13.

FIG. 14 illustrates an example in which a chip extraction module 305 is implemented as a vibration cleaner. The chip extraction module 305 may include a water tank 310 containing liquid L4, a holder 315 provided on an inner wall of the water tank 310 to hold a wiper 140, and a vibration cleaner 320 for supplying vibration to the wiper 140. The vibration cleaner 320 may allow a micro semiconductor chip 130 to be removed by directly applying vibration in contact with the wiper 140. The vibration cleaner 320 may include a vibrator and a plurality of rods configured such that the plurality of rods cross each other to excite the wiper 140. FIG. 14 illustrates an example in which the vibration cleaner 320 includes the plurality of rods. However, the disclosure is not limited thereto. As such, according to another embodiment, the vibration cleaner 320 may include one rod and extract the micro semiconductor chip 130 by applying vibration while the one rod scans the surface of the wiper 140. An excitation frequency of the vibration cleaner 320 may be a frequency in an ultrasonic band.

As described above, an apparatus for collecting a micro semiconductor chip, according to an embodiment, may easily extract and collect a micro semiconductor chip from a wiper coated with a protective layer and thus increase chip collection efficiency and increase a chip recycling rate.

A wiper for transferring a micro semiconductor chip, according to an embodiment, may enable a micro semiconductor chip to be efficiently transferred to a large area by a wet method and may increase a collection rate of the micro semiconductor chip after transferring. An apparatus for collecting a micro semiconductor chip, according to an embodiment, may increase a recycling rate by effectively collecting a micro semiconductor chip remaining on a wiper after transferring the micro semiconductor chip to a transferring substrate.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A wiper comprising:
an absorber configured to absorb a solution used to wet transfer a micro semiconductor chip; and
a protective layer provided on the absorber,
wherein the protective layer comprises a material that does not chemically react to the solution.

2. The wiper of claim 1, wherein the absorber comprises one of fabric, tissue, polyester fiber, or paper.

3. The wiper of claim 1, wherein the protective layer comprises at least one of silk, photoresist, polydimethylsiloxane (PDMS), Teflon, or parylene.

4. The wiper of claim 1, wherein the protective layer is configured to prevent the micro semiconductor chip from penetrating into the absorber.

5. The wiper of claim 1, wherein the protective layer is configured to be removed by acetone (H₂SO₄/KOH/NaOH/toluene) or (ethanol/acetone) or removed by plasma etching.

6. The wiper of claim 1, further comprising a support configured to support the absorber, wherein the absorber is provided on the support.

7. The wiper of claim 1, wherein the protective layer is coated on the absorber.

8. The wiper of claim 1, wherein the protective layer is configured to reduce a number of micro semiconductor chips that penetrate into the absorber.

9. A micro semiconductor chip collection apparatus comprising:
a wiper configured to transfer a plurality of micro semiconductor chips, the wiper comprising:
an absorber configured to absorb a solution used to wet transfer the plurality of micro semiconductor chips, and
a protective layer provided on the absorber;
a chip extraction module configured to remove one or more micro semiconductor chips stuck on the wiper from the wiper; and
a protective layer removal module configured to supply a solution for removing the protective layer from the absorber.

10. The micro semiconductor chip collection apparatus of claim 9, wherein the chip extraction module comprises a liquid spray cleaner, an ultrasonic cleaner, or a vibration cleaner.

11. The micro semiconductor chip collection apparatus of claim 9, wherein the absorber comprises fabric, tissue, polyester fiber, or paper.

12. The micro semiconductor chip collection apparatus of claim 9, wherein the protective layer comprises a material that does not chemically react to the solution.

13. The micro semiconductor chip collection apparatus of claim 9, wherein the protective layer comprises at least one of silk, photoresist, polydimethylsiloxane (PDMS), Teflon, or parylene.

14. The micro semiconductor chip collection apparatus of claim 9, wherein the protective layer is configured to prevent the micro semiconductor chip from penetrating into the absorber.

15. The micro semiconductor chip collection apparatus of claim 9, wherein the protective layer is configured to be removed by acetone (H₂SO₄/KOH/NaOH/toluene) or (ethanol/acetone) or removed by plasma etching.

16. The micro semiconductor chip collection apparatus of claim 9, further comprising a support configured to support the absorber, wherein the absorber is wrapped around the support.

17. The micro semiconductor chip collection apparatus of claim 9, wherein the protective layer is coated on the absorber.

18. The micro semiconductor chip collection apparatus of claim 9, wherein the protective layer is configured to reduce a number of micro semiconductor chips that penetrate into the absorber.

19. A method of collecting a micro semiconductor chip comprising:
providing a solution for forming a protective layer; forming a wiper by coating an absorber with the solution to form the protective layer on the absorber;
transferring the micro semiconductor chip onto a transferring substrate using the wiper; and
collecting the micro semiconductor chip by cleaning the transferring substrate and the wiper.

20. The method of claim 19, further comprises removing the protective layer from the absorber.
